(19) United States
(12) Patent Application Publication
(10) Pub. No.: US 2014/0014979 A1
(43) Pub. Date: Jan. 16, 2014

(54) LIQUID CRYSTAL DISPLAY DEVICE AND MANUFACTURING METHOD THEREFOR

(71) Applicant: Panasonic Liquid Crystal Display Co., Ltd., Himeji-shi (JP)

(72) Inventors: Ryuji MATSUMOTO, Hyogo (JP); Takao TAKANO, Hyogo (JP); Shigekazu HORINO, Osaka (JP)

(21) Appl. No.: 13/939,955

(22) Filed: Jul. 11, 2013

(30) Foreign Application Priority Data
Jul. 12, 2012 (JP) 2012-156986

(51) Int. Cl. H01L 33/00

(52) U.S. Cl. CPC H01L 33/0041
USPC 257/88; 438/22

(57) ABSTRACT

According to a manufacturing method for a liquid crystal display device according to this application, a first terminal hole (3b) for exposure of a part of a gate line (52) is formed in a gate insulating film (3); a pixel hole (8a) for exposure of a part of a drain electrode (57) and a second terminal hole (8b) overlapping the first terminal hole (3b) in a plan view for exposure of a part of the gate line (52) are formed in a lower insulating film (4) and an upper insulating film (8); and a pixel electrode (9) connected to the drain electrode (57) via the pixel hole (8a) and a terminal (92) connected to the gate line (52) via the second terminal hole (8b) are formed.

### CROSS-REFERENCE TO RELATED APPLICATION

The present application claims priority from Japanese application JP2012-156986 filed on Jul. 12, 2012, the entire content of which is hereby incorporated by reference into this application.

### TECHNICAL FIELD

This application relates to a liquid crystal display device and a manufacturing method therefor, and in particular to formation of a hole in an insulating film.

### BACKGROUND

A liquid crystal display device disclosed in Japanese Patent Laid-open Publication No. 2009-047817 has an insulating film 13 covering a thin film transistor Tr, a common electrode 15 formed on the insulating film 13, an insulating film 17 covering the common electrode 15, and a pixel electrode 19 formed on the insulating film 17. In these two layers of insulating films 13, 17, a pixel hole 17a is formed for exposure of a part of a source/drain electrode 11sd of the thin film transistor Tr, and the pixel electrode 19 is connected to the source/drain electrode 11sd via the pixel hole 17a.

In a peripheral region of the liquid crystal display device such as is described above, a terminal hole is formed for exposure of a part of a gate line (a scan line), and a terminal is connected to the gate line via the terminal hole. The terminal hole is formed penetrating three layers of insulating films in total, including two insulating films where the pixel hole is formed and a gate insulating film formed below the two insulating layers.

In simultaneous formation of the terminal hole and the pixel hole through etching, etching for forming a pixel hole that penetrates the two layers of insulating films will continue until completion of formation of a terminal hole that penetrates the three layers of insulating films. This raises a problem that the diameter of the pixel hole results in excessively large.

This application has been conceived in view of the above described situation, and a main object thereof is to provide a liquid crystal display device and a manufacturing method therefor for preventing a diameter of a pixel hole from excessively enlarging.

### SUMMARY

In order to achieve the above mentioned object, according to an embodiment of this application, there is provided a manufacturing method for a liquid crystal display device, comprising forming a gate electrode and a gate line on a transparent substrate; forming a gate insulating film for covering the gate electrode and the gate line; forming a first terminal hole in the gate insulating film for exposure of a part of the gate line; forming a semiconductor layer, a source electrode, and a drain electrode on the gate insulating film; forming a protective insulating film for covering the semiconductor layer, the source electrode, the drain electrode, and the gate line; forming a pixel hole and a second terminal hole in the protective insulating film, the pixel hole for exposure of a part of the source electrode or the drain electrode, and the second terminal hole formed overlapping the first terminal hole in a plan view for exposure of a part of the gate line; and forming a pixel electrode connected to the source electrode or the drain electrode via the pixel hole and a terminal connected to the gate line via the second terminal hole.

In an embodiment of this application, the second terminal hole may be smaller than the first terminal hole and formed inside the first terminal hole.

In an embodiment of this application, the protective insulating film may include a lower insulating film and an upper insulating film, and a common electrode may be formed between the lower insulating film and the upper insulating film.

In an embodiment of this application, the gate insulating film may be harder than the protective insulating film.

According to an embodiment of this application, there is provided a liquid crystal display device, comprising a transparent substrate; a gate electrode and a gate line formed on the transparent substrate; a gate insulating film covering the gate electrode and the gate line; a semiconductor layer, a source electrode, and a drain electrode formed on the gate insulating film; a protective insulating film for covering the semiconductor layer, the source electrode, and the drain electrode; a pixel electrode connected to the source electrode or the drain electrode via the pixel hole formed in the protective insulating film; and a terminal connected to the gate line via the terminal hole formed in the protective insulating film, wherein the protective insulating film directly contacts a part of the gate line that is connected to the terminal.

In an embodiment of this application, the terminal may not contact to the gate insulating film.

In an embodiment of this application, the protective insulating film may include a lower insulating film and an upper insulating film, and a common electrode may be formed between the lower insulating film and the upper insulating film.

According to this application, a first terminal hole is formed in a gate insulating film, and thereafter, a second terminal hole is formed in a protective insulating film so as to overlap the first terminal hole in a plan view. This makes it possible to reduce a period of time necessary to have a part of the gate line exposed, and resultantly to prevent a diameter of a pixel hole from excessively larging to thereby improve an aperture ratio.

### BRIEF DESCRIPTION OF THE DRAWINGS

FIG. 1 is a cross sectional view schematically showing one embodiment of a liquid crystal display device according to this application;

FIG. 2A shows one embodiment of a manufacturing method for a liquid crystal display device according to this application;

FIG. 2B shows one embodiment of a manufacturing method for a liquid crystal display device according to this application;

FIG. 3A is a continuation of FIGS. 2A and 2B;

FIG. 3B is a continuation of FIGS. 2A and 2B;

FIG. 4A is a continuation of FIGS. 3A and 3B;

FIG. 4B is a continuation of FIGS. 3A and 3B;

FIG. 5A is a continuation of FIGS. 4A and 4B;

FIG. 5B is a continuation of FIGS. 4A and 4B;

FIG. 6A is a continuation of FIGS. 5A and 5B;

FIG. 6B is a continuation of FIGS. 5A and 5B;

FIG. 7A is a continuation of FIGS. 6A and 6B;

FIG. 7B is a continuation of FIGS. 6A and 6B;

FIG. 8A is a continuation of FIGS. 7A and 7B;

FIG. 8B is a continuation of FIGS. 7A and 7B;

FIG. 9 shows an example structure of first and second terminal holes;

FIG. 10 shows an example structure of the first and second terminal holes; and

FIG. 11 is a cross sectional view schematically showing another embodiment of a liquid crystal display according to this application.

### DETAILED DESCRIPTION

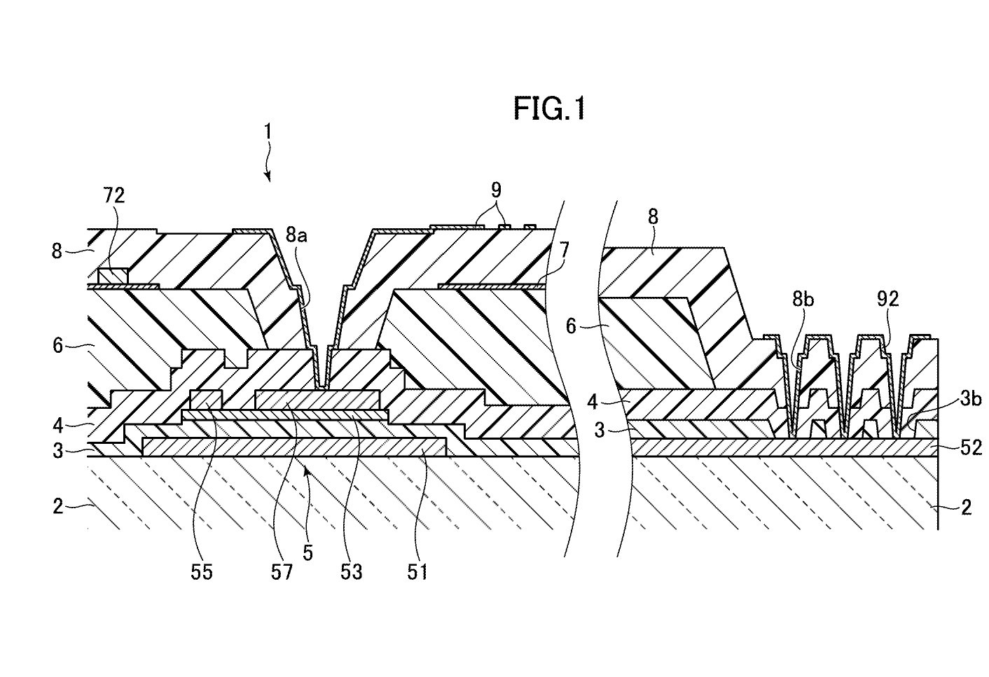

A liquid crystal display device and a manufacturing method therefor according to this application will be described, with reference to the accompanying drawings. FIG. 1 is across sectional view schematically showing one embodiment of a liquid crystal display device according to this application. In this diagram, an area near a thin film transistor (TFT) 5 formed in a display region of a TFT substrate 1 is shown on the left side of the diagram, while an area near a terminal 92 formed in a peripheral region of the TFT substrate 1 is shown on the right side of the diagram.

In the display region of the TFT substrate 1, a TFT 5 is formed on a transparent substrate 2. The TFT 5 includes a gate electrode 51, a semiconductor layer 53, a source electrode 55, and a drain electrode 57. The semiconductor layer 53 is formed on the gate electrode 51. A gate insulating film 3 is formed between the gate electrode 51 and the semiconductor layer 53. The source electrode 55 and the drain electrode 57 are formed on the semiconductor layer 53.

The TFT 5 and the gate insulating film 3 are covered by a lower insulating film 4, or a protective insulating film. The lower insulating film 4 is covered by an organic insulating film 6. The organic insulating film 6 is a planarization film having a flat surface, and formed relatively thick. A common electrode 7 is formed on the organic insulating film 6, and connected to a common line 72. The common electrode 7 and the organic insulating film 6 are covered by an upper insulating film 8, or a protective insulating film. A pixel electrode 9 is formed on the upper insulating film 8. Note that the organic insulating film 6 is not essential.

A hole 6a is formed in the organic insulating film 6 in a position above the drain electrode 57 such that the lower insulating film 4 is exposed at the bottom thereof. The upper insulating film 8 fills the hole 6a, and contacts the lower insulating film 4. A pixel hole 8a is formed in the lower insulating film 4 and the upper insulating film 8, through inside the hole 6a of the organic insulating film 6, such that the drain electrode 57 is exposed at the bottom thereof. The pixel electrode 9 is formed in the pixel hole 8a to be connected to the drain electrode 57.

On a peripheral region of the TFT substrate 1, a gate line 52, connected to the gate electrode 51, extends, and a terminal 92 is connected to an end portion of the gate line 52. The gate insulating film 3, the lower insulating film 4, and the upper insulating film 8 are laminated above the end portion of the gate line 52, but the organic insulating film 6 is not. A first terminal hole 3b is formed in the gate insulating film 3, while a second terminal hole 8b is formed in the lower insulating film 4 and the upper insulating film 8. The first terminal hole 3b and the second terminal hole 8b are formed overlapping each other in a plan view. An end portion of the gate line 52 is exposed at the bottom of the second terminal hole 8b. The terminal 92 is formed in the second terminal hole 8b to be connected to the end portion of the gate line 52.

The transparent substrate 2 is made of non-alkali glass or the like. The gate electrode 51, gate line 52, source electrode 55, and drain electrode 57 of the TFT 5 are made of metal such as Cu, Al, or the like. The semiconductor layer 53 is made of semiconductor such as amorphous Si or the like. The gate insulating film 3, the lower insulating film 4, and the upper insulating film 8 are made of transparent inorganic insulating material, such as SiN or the like. Organic material that constitutes the organic insulating film 6 will be described later. The common electrode 7, the pixel electrode 9, and the terminal 92 are transparent conductive films made of oxide, such as indium-tin oxide (ITO) or the like.

On the TFT substrate 1, an alignment film (not shown) is formed above the upper insulating film 8 and the pixel electrode 9, and a polarizer plate (not shown) is formed below the transparent substrate 2. A liquid crystal layer is sandwiched by the TFT substrate 1 and a color filter (CF) substrate (not shown), whereby a liquid crystal panel is formed. When a driving circuit is mounted on such a liquid crystal panel, a liquid crystal display device is formed.

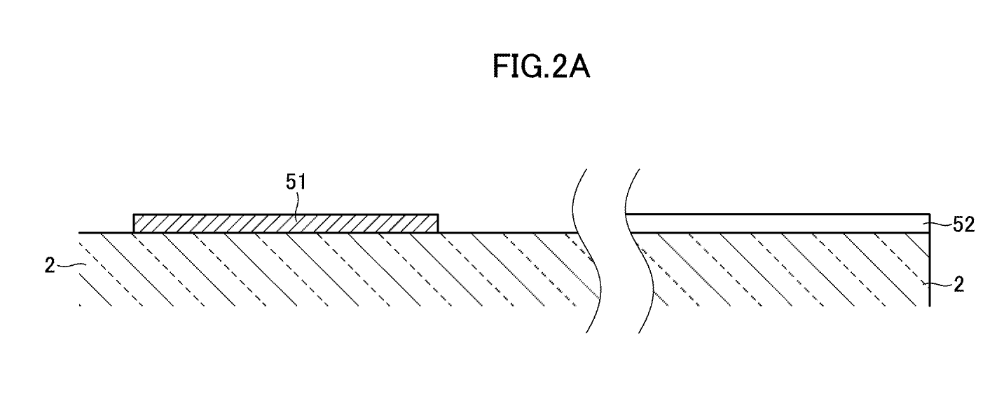

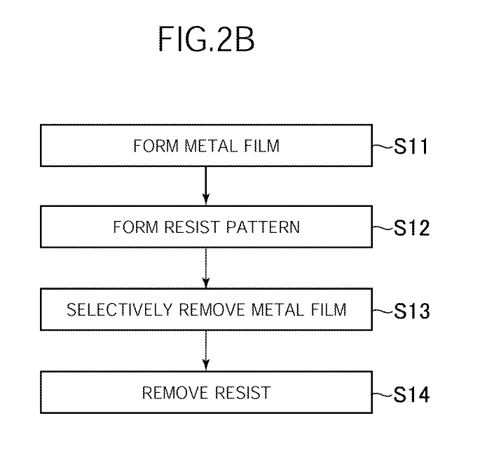

FIGS. 2A to FIG. 8B show an embodiment of a manufacturing method for a liquid crystal display device according to this application. A cross sectional view A in these diagrams shows a state at completion of thin film processing at a photolithography step and through etching, with a photoresist removed, while a flowchart B shows major steps followed before achievement of such a state.

Note here that a photolithography step refers to a step including a series of processing for forming a resist pattern, including coating of photoresist, selective exposure using a photo mask, and development, with detailed description thereof omitted below.

At the steps shown in FIGS. 2A and 2B, the gate electrode 51 and the gate line 52 are formed. Specifically, initially, a metal film made of metal such as Cu, Al, and so forth, is formed on the transparent substrate 2 through sputtering (S11). Then, a resist pattern is formed on the metal film (S12), and the metal film is selectively etched (S13). Thereafter, the photoresist is removed (S14). With the above, the gate electrode 51 and the gate line 52 are formed on the transparent substrate 2.

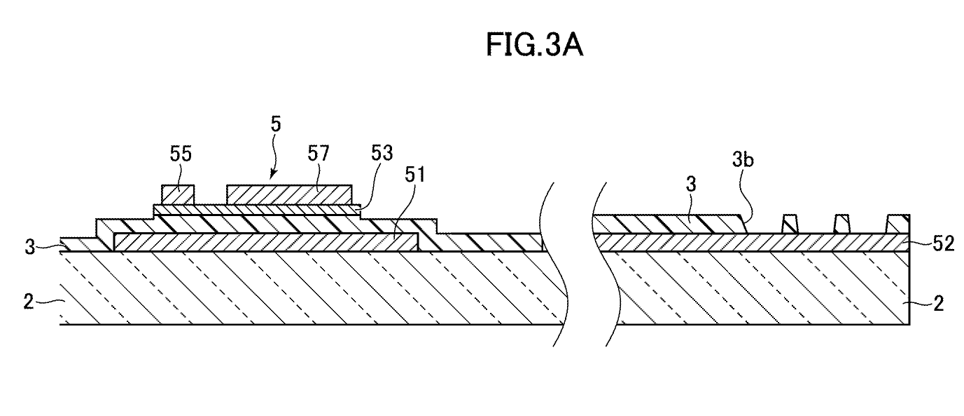

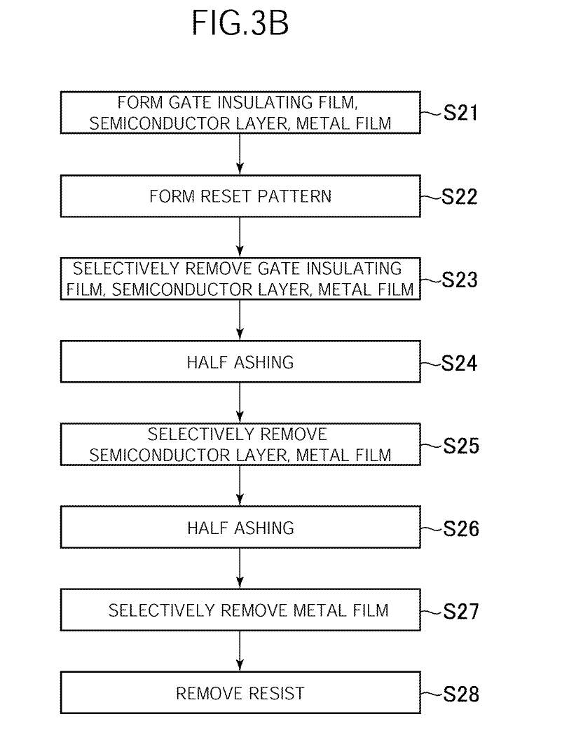

At the steps shown in FIGS. 3A and 3B, the gate insulating film 3, the semiconductor layer 53, the source electrode 55, and the drain electrode 57 are formed. Further, the first terminal hole 3b is formed in the gate insulating film 3. Specifically, ammonia gas, silane gas, and nitrogen gas are introduced into a reaction chamber of a CVD device to form a gate insulating film 3 made of SiNx. Then, silane gas and hydrogen gas are introduced to form a semiconductor layer made of amorphous Si, and a metal film made of metal such as Cu, Al, and so forth is thereafter formed through sputtering (S21).

Thereafter, a resist pattern using a halftone mask is formed on the metal film (S22). Note here that a photoresist having a first thickness is formed in a region where the source electrode 55 and the drain electrode 57 are formed, and a photoresist having a second thickness being thinner than the first thickness is formed in a region between the source electrode 55 and the drain electrode 57. A photoresist having a third thickness being thinner than the second thickness is formed in a region free from the semiconductor layer 53, and no photoresist is formed in a region where the first terminal hole 3b is formed. Then, the metal film, the semiconductor layer, and the gate insulating film 3 are selectively etched (S23), whereby the first terminal hole 3b is formed in the gate insulating film 3 such that an end portion of the gate line 52 is exposed at the bottom thereof. Then, a part of the photoresist having the third thickness is removed by half asking (S24), and the metal film and the semiconductor layer in the thereby exposed region is selectively etched (S25). Thereafter, a part of the photoresist having the second thickness is removed through half-asking (S26), and the metal film in the thereby exposed region is etched (S27). Thereafter, the photoresist is removed (S26). With the above, the semiconductor layer 53, the source electrode 55, and the drain electrode 57 are formed, whereby the TFT 5 is completed.

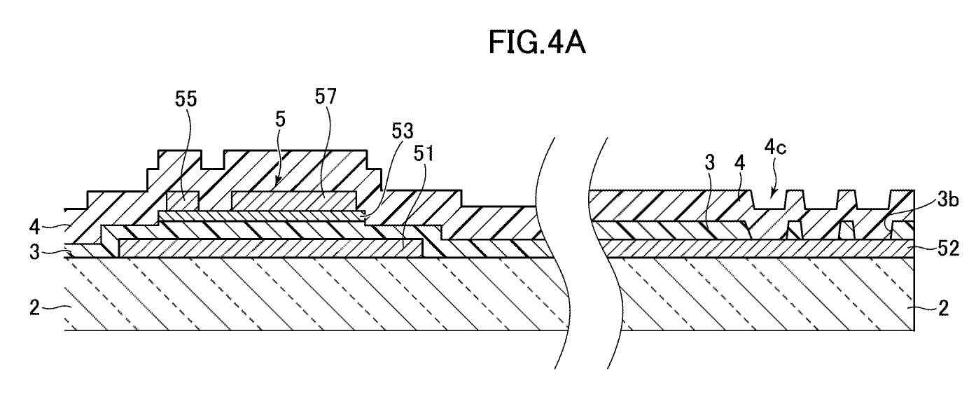

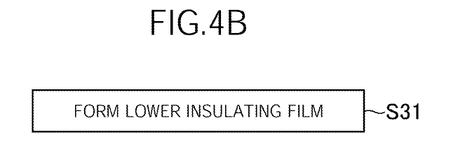

At the steps shown in FIGS. 4A and 4B, the lower insulating film 4 is formed. Specifically, ammonia gas, silane gas, and nitrogen gas are introduced into the reaction chamber of the CVD device to form the lower insulating film 4 made of SiNx on the TFT 5 and the gate insulating film 3 (S31). In the above, as the lower insulating film 4 fills the first terminal hole 3b formed in the gate insulating film 3, a recess 4c having a shape imitating the shape of the first terminal hole 3b is formed above the first terminal hole 3b.

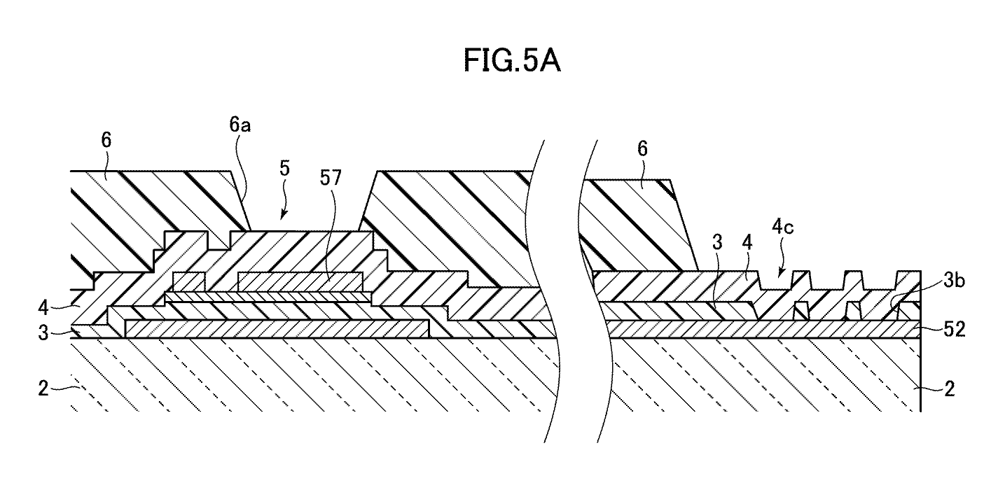

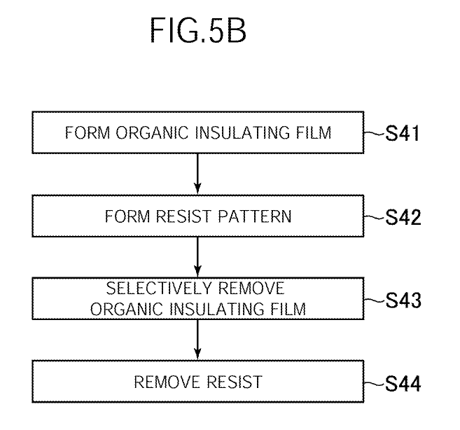

At the steps shown in FIGS. 5A and 5B, the organic insulating film 6 is formed. Specifically, liquid organic material is coated on the lower insulating film 4 and cured, whereby the organic insulating film 6 is formed (S41). Acrylic resin, for example, may be available as organic material for forming the organic insulating film 6, though this is not limiting, and silicone resin, epoxy resin, polyimide resin, and so forth, are also usable. The organic insulating film 6 may include inorganic filling member, such as silica, or the like. The organic insulating film 6 is a paternarization film having a flat surface and thicker than the lower insulating film 4 and the upper insulating film 8. Thereafter, a resist pattern is formed on the organic insulating film 6 (S42). The organic insulating film 6 is selectively etched (S43), and the photoresist is then removed (S44). With the above, a hole 6a is formed in the organic insulating film 6 above the drain electrode 57 such that the lower insulating film 4 is exposed at the bottom thereof. Note that the organic insulating film 6 is not formed above an end portion of the gate line 52.

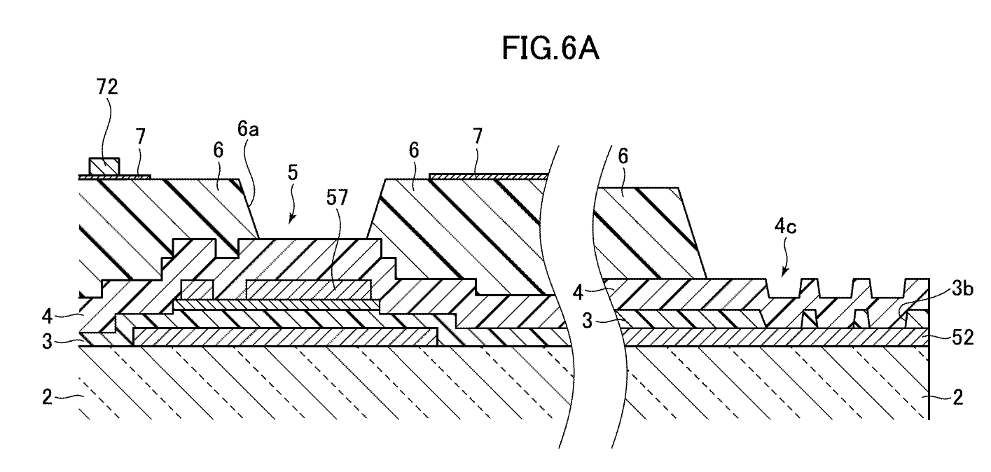

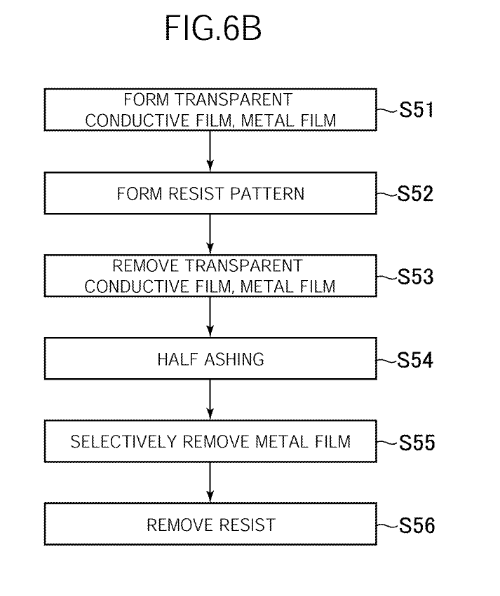

At the steps shown in FIGS. 6A and 6B, the common electrode 7 and the common line 72 are formed. Specifically, a transparent conductive film made of oxide, such as ITO, or the like, is formed on the organic insulating film 6 through sputtering, and a metal film made of metal, such as Cu, Al, or the like is further formed through sputtering (S51). Thereafter, a resist pattern using a halftone mask is formed on the metal film (S52). Note here that a photoresist is formed relatively thick in a region where the common line 72 is formed, and relatively thin in a region where the common electrode 7 alone is formed, and no photoresist is formed in a region without the common electrode 7. Then, the metal film and the transparent conductive film are selectively etched (S53). Further, a part of the photoresist that is formed thin is removed through half asking (S54), and the metal film in the thereby exposed region is etched (S55). Thereafter, the photoresist is removed (S56). With the above, the common electrode 7 and the common line 72 are formed.

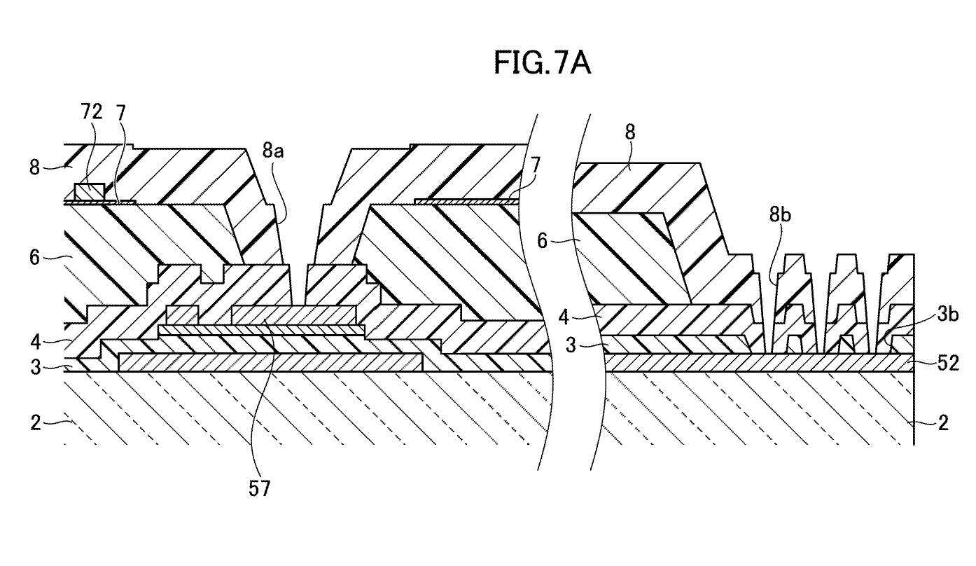

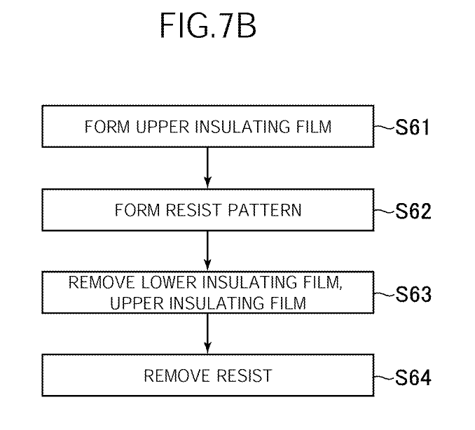

At the steps shown in FIGS. 7A and 7B, the upper insulating film 8 is formed. Specifically, ammonia gas, silane gas, and nitrogen gas are introduced into the reaction chamber of the CVD device to form an upper insulating film 8 made of SiNx on the organic insulating film 6 (S61). In the above, the upper insulating film 8 fills the hole 6a formed in the organic insulating film 6 and contacts the lower insulating film 4 exposed at the bottom of the hole 6a. Further, the upper insulating film 8 also contacts the lower insulating film 4 in a position above an end portion of the gate line 52. Then, a resist pattern is formed on the upper insulating film 8 (S62); the upper insulating film 8 is selectively etched (S63); and the photoresist is then removed (S64).

With the above, in the display region of the TFT substrate 1, the pixel hole 8a is formed in two layers including the lower insulating film 4 and the upper insulating film 8 through inside the hole 6a of the organic insulating film 6 such that the drain electrode 57 is exposed at the bottom thereof. Meanwhile, in a peripheral region of the TFT substrate 1 as well, the second terminal hole 8b is formed in two layers including the lower insulating film 4 and the upper insulating film 8 so as to overlap the first terminal hole 3b in a plan view such that an end portion of the gate line 52 is exposed at the bottom thereof. That is, as the first terminal hole 3b is formed in the gate insulating film 3 in this embodiment, the number of insulating films in which the second terminal hole 8b should be formed is two, that is, two layers including the lower insulating film 4 and the upper insulating film 8. This is the same number as the number of insulating films in which the pixel hole 8a should be formed. Therefore, with the above, in simultaneous formation of the pixel hole 8a and the second terminal hole 8b, a period of time necessary to have the gate line 52 exposed is substantially equal to or differs only substantially small from that necessary to have the drain electrode 57 exposed. As a result, it is possible to prevent a diameter of the pixel hole 8a from excessively larging.

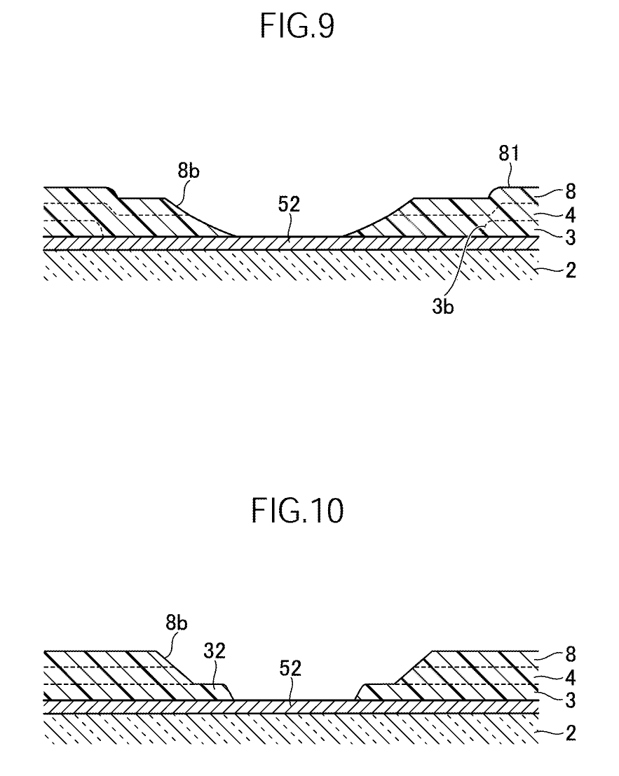

FIG. 9 shows a specific example of a structure of the first terminal hole 3b and the second terminal hole 4b. In this example structure, the second terminal hole 8b is smaller than and formed inside the first terminal hole 3b. Therefore, a part of the gate line 52, to which the terminal 92 is connected is covered not by the gate insulating film 3 but by the lower insulating film 4. In detail, a region around a part of the gate line 52 that is exposed in the second terminal hole 8b is covered by the lower insulating film 4. When the second terminal hole 8b is formed in the lower insulating film 4 and the upper insulating film 8, as described above, the terminal 92 formed in the second terminal hole 8b (see FIG. 1) does not contact the gate insulating film 3.

Note here that as the gate insulating film 3 is formed together with the semiconductor layer 53 (see FIGS. 3A and 3B), the film formation temperature of the gate insulating film 3 is higher than that of the lower insulating film 4 and the upper insulating film 8. For example, the film formation temperature of the gate insulating film 3 is about 350° C., and that of the lower insulating film 4 and the upper insulating film 8 is about 290° C. Because of the difference in the formation temperature, the gate insulating film 3 becomes harder than the lower insulating film 4 and the upper insulating film 8, being thus inferior in processability. However, in the example structure shown in FIG. 9, the second terminal hole 8b is formed in the lower insulating film 4 and the upper insulating film 8, both being relatively superior in processability, rather than in the gate insulating film 3 being relatively inferior in processability, it is possible to readily form the second terminal hole 8b into a desired tapered shape, and thus to improve reliability of the terminal 92.

Note that as the gate insulating film 3, the lower insulating film 4, and the upper insulating film 8 are made of the same material, boundaries therebetween cannot be readily determined. However, whether or not the second terminal hole 8b is smaller than and formed inside the first terminal hole 3b can be determined based on whether or not a mound portion 81 corresponding to the gate insulating film 3 is formed on the upper surface of the upper insulating film 8.

Note that the above described aspect is not limiting, and that the second terminal hole 8b may be formed larger than and outside the first terminal hole 3b, as shown in FIG. 10. In this case, the first terminal hole 3b and the second terminal hole 8b are successive, with the inside wall thereof resulting in a stepped shape. That is, a projected portion 32 projecting more inward than the lower insulating film 4 and the upper insulating film 8 is formed on the gate insulating film 3.

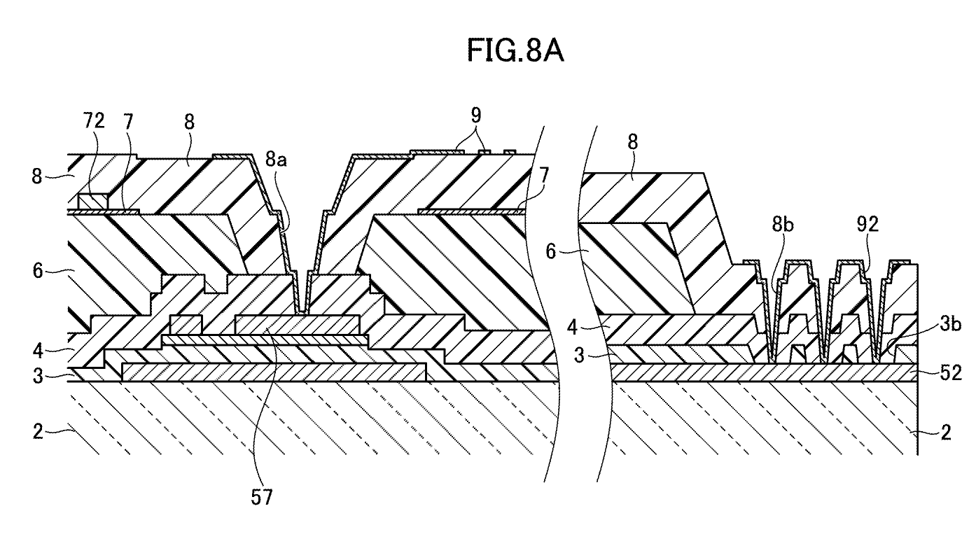

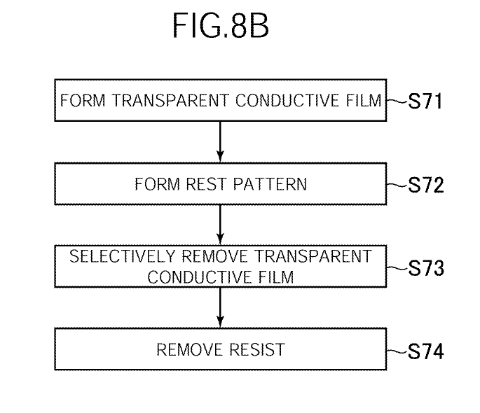

Returning to the description on the manufacturing process, the pixel electrode 9 and the terminal 92 are formed at the steps shown in FIGS. 8A and 8B. Specifically, a transparent conductive film made of oxide such as ITO or the like is formed through sputtering on the upper insulating film 8 (S71). Thereafter, a resist pattern is formed on the transparent conductive film (S72). Then, the transparent conductive film is selectively etched (S73). Thereafter, the photoresist is removed (S74). With the above, the pixel electrode 9 is formed on the upper insulating film 8, and in the pixel hole 8a to be connected to the drain electrode 57 exposed at the bottom of the pixel hole 8a. Still further, the terminal 92 is formed in the second terminal hole 8b to be connected to an end portion of the gate line 52 exposed at the bottom of the second terminal hole 8b.

Thereafter, an alignment film (not shown) is formed above the upper insulating film 8 and the pixel electrode 9, and a polarizer plate (not shown) is formed below the transparent substrate 2, whereby the TFT substrate 1 is completed. Further, a liquid crystal layer is held between the TFT substrate 1 and a CF substrate (not shown), whereby the liquid crystal panel is completed. When a driving circuit or the like is mounted on such a liquid crystal panel, a liquid crystal display device is completed.

Although an embodiment of this application has been described in the above, this application is not limited to the above described embodiment, and various modified embodiments are possible for a person skilled in the art.

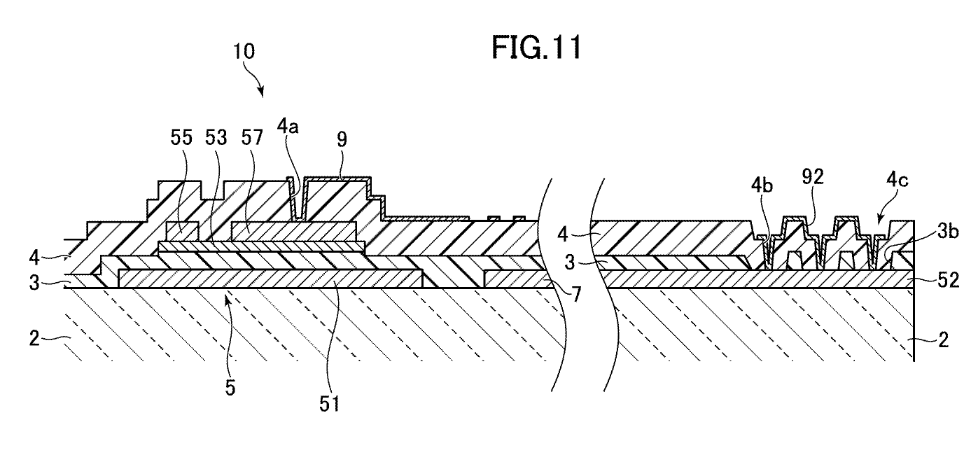

This application may be applied to a TFT substrate 10 such as is shown in FIG. 11. In the TFT substrate 10, the pixel electrode 9 is formed on the protective insulating film 4, and the common electrode 7 is formed under the gate insulating film 3. In the display region of the TFT substrate 10, the pixel hole 8a is formed in the protective insulating film 4 such that the drain electrode 57 is exposed at the bottom thereof. In a peripheral region of the TFT substrate 10, the second terminal hole 4b is formed in the protective insulating film 4 so as to overlap the first terminal hole 3b in a plan view such that an end portion of the gate line 52 is exposed at the bottom thereof. That is, in this modified example as well, as the first terminal hole 3b is formed in the gate insulating film 3, the number of insulating films in which the terminal hole 4b should be formed is one, that is, only one layer of the protective insulating film 4. This is the same number as the number of insulating in which the pixel hole 4a should be formed.

While there have been described what are at present considered to be certain embodiments of the invention, it will be understood that various modifications may be made thereto, and it is intended that the appended claims coverall such modifications as fall within the true spirit and scope of the invention.

What is claimed is:

1. A manufacturing method for a liquid crystal display device, comprising:
forming a gate electrode and a gate line on a transparent substrate;
forming a gate insulating film for covering the gate electrode and the gate line;
forming a first terminal hole in the gate insulating film for exposure of a part of the gate line;
forming a semiconductor layer, a source electrode, and a drain electrode on the gate insulating film;
forming a protective insulating film for covering the semiconductor layer, the source electrode, the drain electrode, and the gate line;
forming a pixel hole and a second terminal hole in the protective insulating film, the pixel hole for exposure of a part of the source electrode or the drain electrode, and the second terminal hole formed overlapping the first terminal hole in a plan view for exposure of a part of the gate line; and
forming a pixel electrode connected to the source electrode or the drain electrode via the pixel hole and a terminal connected to the gate line via the second terminal hole.

2. The manufacturing method for a liquid crystal display device according to claim 1, wherein the second terminal hole is smaller than the first terminal hole and formed inside the first terminal hole.

3. The manufacturing method for a liquid crystal display device according to claim 1, wherein
the protective insulating film includes a lower insulating film and an upper insulating film, and
a common electrode is formed between the lower insulating film and the upper insulating film.

4. The manufacturing method for a liquid crystal display device according to claim 2, wherein the gate insulating film is harder than the protective insulating film.

5. A liquid crystal display device, comprising:
a transparent substrate;
a gate electrode and a gate line formed on the transparent substrate;
a gate insulating film covering the gate electrode and the gate line;
a semiconductor layer, a source electrode, and a drain electrode formed on the gate insulating film;
a protective insulating film for covering the semiconductor layer, the source electrode, and the drain electrode;
a pixel electrode connected to the source electrode or the drain electrode via the pixel hole formed in the protective insulating film; and
a terminal connected to the gate line via the terminal hole formed in the protective insulating film, wherein
the protective insulating film directly contacts a part of the gate line that is connected to the terminal.

6. The liquid crystal display device according to claim 5, wherein the terminal doesn't contact to the gate insulating film.

7. The liquid crystal display device according to claim 5, wherein the protective insulating film includes a lower insulating film and an upper insulating film, and
a common electrode is formed between the lower insulating film and the upper insulating film.
